(19) United States
(12) Patent Application Publication
(10) Pub. No.: US 2010/0304280 A1
(43) Pub. Date: Dec. 2, 2010

(54) METHOD OF FORMING A TEMPLATE, AND METHOD OF MANUFACTURING A SEMICONDUCTOR DEVICE USING THE TEMPLATE

(76) Inventor: Masayuki HATANO, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/718,370

(22) Filed: Mar. 5, 2010

(30) Foreign Application Priority Data
May 26, 2009 (JP) P2009-125997

(51) Int. Cl. G03F 1/00; G03F 7/20

(52) U.S. Cl. 430/5; 430/30

(57) ABSTRACT

A method of manufacturing a semiconductor device using a template on which a pattern is formed beforehand is disclosed. An error between a position of the pattern formed on the template and a reference position where the pattern is to be formed is obtained. An outer shape of the template is processed in accordance with the obtained error. The error of the template is corrected by distorting the template through application of pressure to a side face of the template whose outer shape is processed. The pattern is transferred onto a transfer layer formed on a semiconductor substrate by using the template in which the error is corrected.

### CROSS REFERENCE TO RELATED APPLICATION

This application is based upon and claims the benefit of priority from the prior Japanese Patent Application No. 2009-125997, filed on May 26, 2009, the entire contents of which are incorporated herein by reference.

### FIELD OF THE INVENTION

This invention relates to a method of forming a template and a method of manufacturing a semiconductor device using the template.

### DESCRIPTION OF THE BACKGROUND

A circuit pattern of a semiconductor device is formed by transferring a pattern, which is formed on a mask, onto a resist formed on a wafer, by a photolithography process.

An exposure apparatus used for the photolithography process is getting more expensive with miniaturization of a circuit pattern. The cost for forming a mask, which is used in the photolithography process in order to obtain resolution substantially equal to the wavelength of the used light, is also getting more expensive. Because of these reasons, the increase in the manufacturing cost of the photolithography process has been a problem. An imprint process is known as a pattern forming technique to solve the problem.

In the imprint process, a template, on which a pattern to be formed is formed, is pressed against a pattern transferring layer which is made of a resin formed on the wafer, whereby the pattern on the template is transferred onto the pattern transferring layer. The pattern formed on the template is formed in such a manner that a substrate is printed by an electric beam and etched.

The imprint process includes a thermal imprint process and an optical imprint process. In the thermal imprint process, a resin layer serving as the pattern transferring layer is melted by heat. After a template is pressed against the resin layer, the resin layer is cooled and hardened, whereby the pattern on the template is transferred onto the resin layer. In the optical imprint process, a transparent template made of a glass or the like is pressed against a resin layer made of a photo-curable resin, and then, the resin layer is irradiated with ultraviolet ray, so that the resin layer is hardened. Thus, the pattern on the template is transferred onto the resin layer.

In the imprint processes described above, the pattern formed on the template is transferred over a circuit pattern formed on the wafer surface beforehand. Therefore, the positional error of the pattern formed on the template becomes the alignment error, which causes a problem of poor alignment accuracy.

In manufacturing a semiconductor device which includes a multi-layer wiring layer formed by electrically connecting a first circuit pattern on the surface of a wafer with a second circuit pattern on an insulating film formed on the first circuit pattern through a via hole formed in the insulating film, the pattern alignment accuracy means the alignment accuracy between the wiring of the first circuit pattern and the via hole. If the alignment accuracy is poor, a disadvantage that the via hole is formed at a position outside the wiring of the first circuit pattern arises.

To address the problem as described above, there has been known an imprint process in which a size of a pattern formed on a template is corrected through compression of the template, so that the pattern formed on the template is matched to the size of a pattern on the surface of a wafer and transferred onto a resin layer, as described in Japanese Patent Application Publication No. 2005-5284. According to the imprint process, the size of the pattern on the surface of the wafer and the size of the pattern transferred onto the resin layer are matched, whereby the alignment accuracy can be enhanced.

However, the pattern on the template used in the imprint process is formed with a positional error, because of a positional deviation caused by an electron beam lithography system used for forming the pattern on the template. On the other hand, the circuit pattern on the surface of the wafer is formed by an exposure apparatus that transfers a master of a mask onto the wafer. The circuit pattern on the surface of the wafer is also formed with the positional deviation because of the positional error upon transferring the pattern due to a distortion of the exposure apparatus and the error in the positional accuracy of the pattern of the master of the mask.

Accordingly, it is difficult to enhance the alignment accuracy between the circuit pattern on the surface of the wafer and the pattern formed on the resin layer only by reducing the size of the pattern, which is achieved by compressing the template, or the positional correction in the x-direction and y-direction of the template.

### SUMMARY OF THE INVENTION

A method of forming a template according to an embodiment of the invention includes: obtaining an error between a position of the pattern formed on the template and a reference position where the pattern is to be formed; and processing an outer shape of the template in accordance with the obtained error.

A method of manufacturing a semiconductor device using a template according to an embodiment of the invention includes: obtaining an error between a position of the pattern formed on the template and a reference position where the pattern is to be formed; processing an outer shape of the template in accordance with the obtained error; correcting the error of the template by distorting the template through application of pressure to a side face of the template whose outer shape is processed; and transferring the pattern onto a transfer layer formed on a semiconductor substrate by using the template in which the error is corrected.

### BRIEF DESCRIPTION OF THE DRAWINGS

FIG. 1 is a flowchart to explain a method of manufacturing a semiconductor device according to a first embodiment of the invention,

FIG. 2 is a view used to explain a method of forming a template according to the method of manufacturing a semiconductor device shown in FIG. 1 and shows a template before processing,

FIG. 3 is a vector map used to explain the method of forming a template according to the method of manufacturing a semiconductor device shown in FIG. 1 and indicates a deviation amount of a pattern position of the template,

FIG. 4 is a graph used to explain the method of forming a template according to the method of manufacturing a semiconductor device shown in FIG. 1 and shows a relationship between a coefficient at each term in a correction equation and the deviation amount of the pattern position corresponding to the coefficient,

FIG. 5 is a view used to explain the method of forming a template according to the method of manufacturing a semiconductor device shown in FIG. 1 and shows an outer shape of the processed template,

FIG. 6 is a view used to explain the method of forming a template and shows a state in which a protection film is applied onto the template,

FIG. 7 is a sectional view taken along a broken line X-X′ in FIG. 6,

FIG. 8 is a view used to explain the method of forming a template and shows a state in which side faces of the template are ground,

FIG. 9 is a view used to explain the method of manufacturing a semiconductor device according to the first embodiment of the invention, and shows a state in which the template shown in FIG. 8 is clamped,

FIG. 10 is a view used to explain the method of manufacturing a semiconductor device according to the first embodiment of the invention, and shows an outer shape of the template that is distorted as a result of clamping the template,

FIG. 11 is a sectional view taken along a broken line X-X′ in FIG. 9,

FIG. 12 is a view used to explain the method of manufacturing a semiconductor device according to the first embodiment of the invention, and shows a state in which the template is pressed against a resist,

FIG. 13 is a view used to explain the method of manufacturing a semiconductor device according to the first embodiment of the invention, and shows a state in which the position of the template is corrected,

FIG. 14 is a view used to explain the method of manufacturing a semiconductor device according to the first embodiment of the invention, and shows a state in which the pattern is transferred onto the resist,

FIG. 15 is a view used to explain the method of manufacturing a semiconductor device according to the first embodiment of the invention, and used to explain the relative positional deviation between a shot position and the position where the template is pressed,

FIG. 16 is a flowchart used to explain a method of manufacturing a semiconductor device according to a second embodiment of the invention,

FIG. 17 is a flowchart used to explain a method of manufacturing a semiconductor device according to a third embodiment of the invention,

FIG. 18 shows a template whose front surface is processed,

FIG. 19 is a sectional view taken along a broken line X-X′ in FIG. 18,

FIG. 20 shows a template whose back surface is processed,

FIG. 21 is a sectional view taken along a broken line X-X′ in FIG. 20,

FIG. 22 shows another mode of a vector map,

FIG. 23 shows an outer shape of a template whose side faces are processed according to the vector map in FIG. 22,

FIG. 24 shows an outer shape of a template whose front surface is processed according to the vector map in FIG. 22,

FIG. 25 shows another mode of a vector map,

FIG. 26 shows an outer shape of a template whose side faces are processed according to the vector map in FIG. 25,

FIG. 27 shows an outer shape of a template whose front surface is processed according to the vector map in FIG. 25,

FIG. 28 shows an outer shape of a template whose back surface is processed according to the vector map in FIG. 25,

FIG. 29 shows another mode of a vector map,

FIG. 30 shows an outer shape of a template whose side faces are processed according to the vector map in FIG. 29,

FIG. 31 shows an outer shape of a template whose front surface is processed according to the vector map in FIG. 29,

FIG. 32 shows an outer shape of a template whose back surface is processed according to the vector map in FIG. 29,

FIG. 33 shows another mode of a vector map,

FIG. 34 shows an outer shape of a template whose side faces are processed according to the vector map in FIG. 33,

FIG. 35 shows an outer shape of a template whose front surface is processed according to the vector map in FIG. 33,

FIG. 36 shows an outer shape of a template whose back surface is processed according to the vector map in FIG. 33,

FIG. 37 shows another mode of a vector map,

FIG. 38 shows an outer shape of a template whose side faces are processed according to the vector map in FIG. 37,

FIG. 39 shows an outer shape of a template whose front surface is processed according to the vector map in FIG. 37,

FIG. 40 shows an outer shape of a template whose back surface is processed according to the vector map in FIG. 37, and

FIG. 41 shows an outer shape of a template when a pattern on the template is enlarged and transferred.

### DETAILED DESCRIPTION OF THE INVENTION

Embodiments of the invention will be described with reference to the drawings.

### First Embodiment

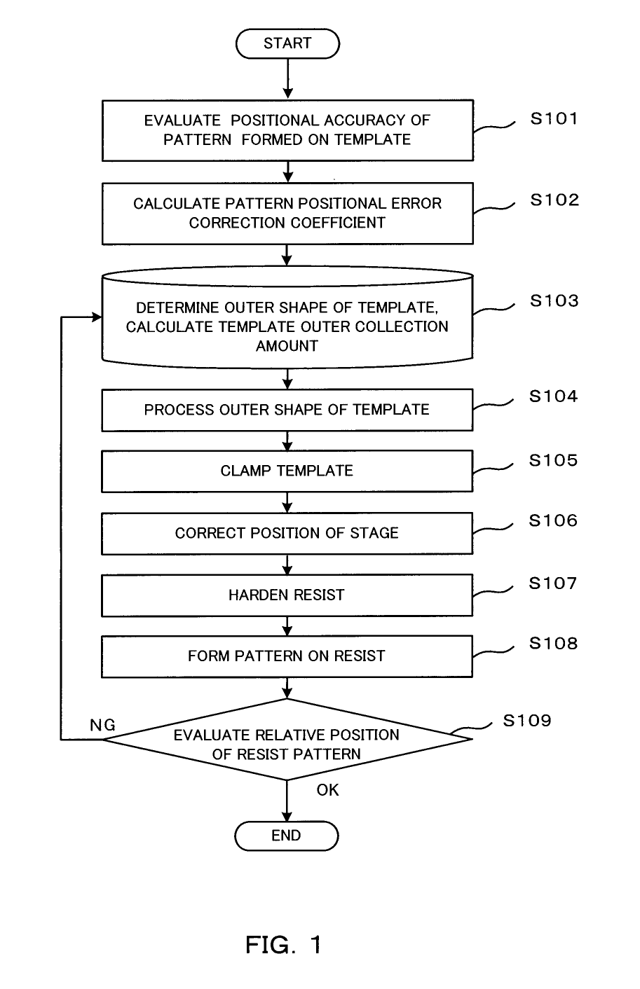

A first embodiment of a method of manufacturing a semiconductor device according to the invention will be described with reference to FIG. 1. FIG. 1 is a flowchart that explains the method of manufacturing a semiconductor device according to the first embodiment of the invention.

The method of manufacturing a semiconductor device shown in FIG. 1 includes a process of forming a template in which an imprint-template is formed into a desired outer shape, and an imprint process using the formed template.

The process of forming the imprint-template will be described first.

Firstly, a positional accuracy of a pattern formed on the template is evaluated (step S101).

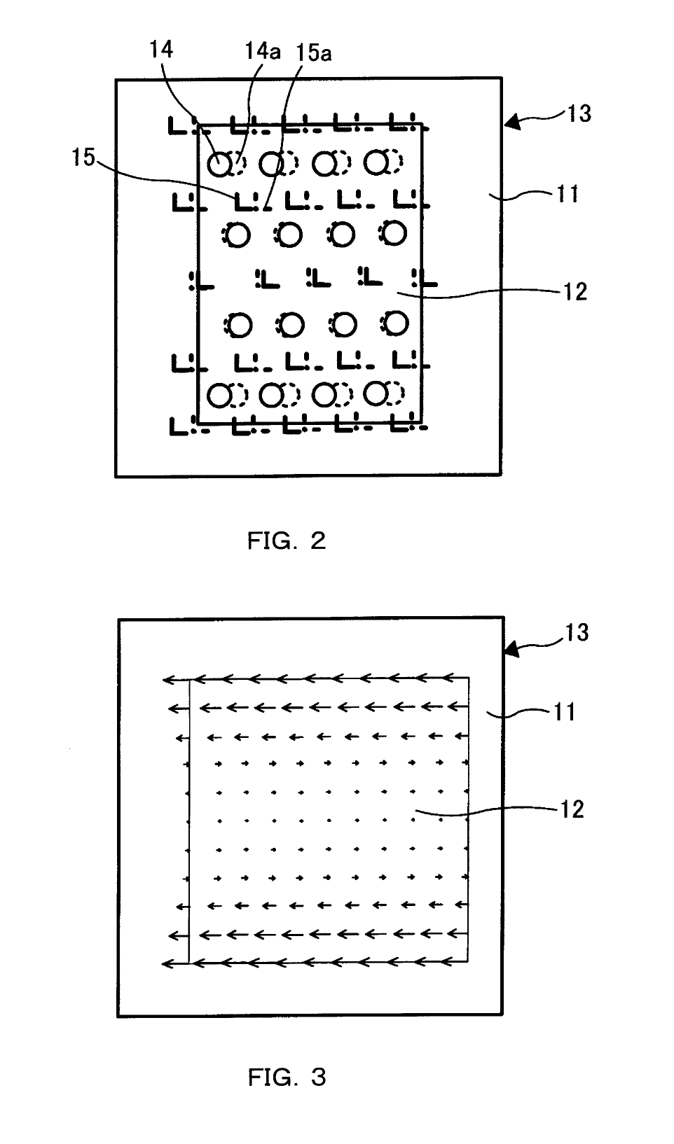

As shown in FIG. 2, a pattern is formed on a central portion 12 of a glass substrate 11 by an electron beam lithography and etching, whereby a template 13 is formed. The pattern formed on the central portion 12 of the template 13 includes a desired pattern such as a circuit pattern and a mark 15 used for the positional evaluation. A plurality of marks 15 are formed in a lattice, for example, and each mark has an L-shape. Each of the marks 15 is formed on an area where the circuit pattern is not formed, such as the area corresponding to a dicing line. Reference marks 26-1, 26-2 shown in FIG. 13 and box-like marks 27-1, 27-2 shown in FIG. 15 are also formed on the template 13 in addition to the marks 15.

The pattern positional accuracy means the absolute positional deviation of the marks 15 or other patterns formed on the template 13. Specifically, the pattern positional accuracy means the positional deviation of the marks 15 or the other patterns from reference positions (designed positions). As shown in FIG. 2, for example, the pattern positional accuracy in the template 13 having isolated patterns 14 and the marks 15 formed in a lattice is represented by the positional deviation of each isolated pattern 14 from a reference position 14a or the positional deviation of each mark 15 from a reference position 15a.

The evaluation of the pattern positional accuracy of the template 13 means the measurement of the deviation amount (degree of error) of the isolated patterns 14 and the marks 15 from the corresponding reference positions.

Next, a pattern positional error correction coefficient, which corrects the pattern positional accuracy, is calculated from the positional deviation amount (degree of error) obtained by the evaluation of the pattern positional accuracy of the template 13 (step S102).

When the position of the actual mark 15 on the coordinate is (x′, y′) and the reference position of the reference mark 15 on the coordinate is (x, y) at step S101 in FIG. 1, for example, the positional deviation amount of the mark 15 is calculated from (x′−x, y′−y). It is supposed that the coordinate has an x axis and y axis, and the lower-left point of the central portion 12 of the template 13 having the pattern formed thereon is defined as an origin.

The positional deviation amount calculated as described above may be represented as a vector map as illustrated in FIG. 3, for example. In the vector map shown in FIG. 3, the positional deviation amount (xi′−xi, yi′−yi) (i corresponds to each of the marks 15) of each mark 15 is represented by vectors. Specifically, the vector map indicates that, the longer the vector is, the greater the positional deviation amount of the mark 15 with respect to the reference position 15a is, which means the pattern positional accuracy is poor.

The pattern positional error correction coefficient that corrects the pattern positional accuracy is calculated as described below.

When the position of the mark 15 corrected by the correction equation described below is defined as (dxi′, dyi′), and the positional deviation amount of the mark 15 is defined as (dxi, dyi) (where i represents the evaluation point of each mark 15, i=0 . . . m), the error at each evaluation point after the correction, i.e., a square sum E of the difference between the corrected position and the positional deviation amount of the pattern is expressed by the equation (1).

$$E = {\sum }_{i = 1}^{m} [ {( {dxi}^{′} - dxi )}^{2} ] + [ {( {dyi}^{′} - dyi )}^{2} ] \qquad ( 1 )$$

In the equation, m is the number of the marks 15 whose positional accuracy is evaluated.

The corrected position (dxi′, dyi′) of the mark 15 obtained from the reference position (xi, yi) of each mark 15 and the later-described correction coefficients k1, k2, k3, k4, k5, k6, k7, k11, k12, k13, and k19 is expressed by the correction equation described in the equation (2).

$${dxi}^{′} = {k}_{1} + {k}_{3} \times xi + {k}_{5} \times yi + {k}_{7} \times {xi}^{2} + {k}_{11} \times {yi}^{2} + {k}_{13} \times {xi}^{3} + {k}_{19} \times {yi}^{3} \\ {dyi}^{′} = {k}_{2} + {k}_{6} \times xi + {k}_{4} \times yi + {k}_{12} \times {xi}^{2} \qquad ( 2 )$$

The correction coefficients of the respective terms in the equation (2) represent the respective positional deviation components. The term of the correction coefficient k1 represents the positional deviation component in the x direction, while the term of the correction coefficient k2 represents the positional deviation component in the y direction. The term of the correction coefficient k3 represents the scale component in the x direction, while the term of the correction coefficient k4 represents the scale component in the y direction. The term of the correction coefficient k5 represents the rotational deviation component with respect to the x axis, while the term of the correction coefficient k6 represents the rotational deviation component with respect to the y axis. The coefficients of these terms are correction parameters of primary components (linear components), and can be corrected by moving a stage. In contrast, the term of the correction coefficient k7 represents an eccentricity ratio component. The term of the correction coefficient k11 represents an arched component with respect to the y axis, while the term of the correction coefficient k12 represents an arched component with respect to the x axis. The term of the correction coefficient k13 represents a tertiary magnification component with respect to the x axis, while the term of the correction coefficient k19 represents a tertiary magnification component with respect to the y axis. The coefficients of these terms are correction parameters of high-order components (non-linear components), and represent the positional deviation component that cannot be corrected only by the movement of the stage.

The pattern positional error correction coefficient is a coefficient of each of the terms when the square sum E of the equation, which is obtained by substituting the correction equation of the equation (2) into the equation (1), is made the minimum. The pattern positional error correction coefficient is calculated by solving the normal equation indicated in the equation (3) below.

$$[ \begin{matrix}Σ1 & Σ xi & Σ yi & Σ {xi}^{2} & Σ {yi}^{2} & Σ {xi}^{3} & Σ {yi}^{3} \\ Σ xi & Σ {xi}^{2} & Σ xiyi & Σ {xi}^{3} & Σ {xiyi}^{2} & Σ {xi}^{4} & Σ {xiyi}^{3} \\ Σ yi & Σ xiyi & Σ {yi}^{2} & Σ {xi}^{2} yi & Σ {yi}^{3} & Σ {xi}^{3} yi & Σ {yi}^{4} \\ Σ {xi}^{2} & Σ {xi}^{3} & Σ {xi}^{2} yi & Σ {xi}^{3} & Σ {xi}^{2} {yi}^{2} & Σ {xi}^{5} & Σ {xi}^{2} {yi}^{3} \\ Σ {yi}^{2} & Σ {xiyi}^{2} & Σ {yi}^{3} & Σ {xi}^{2} {yi}^{2} & Σ {yi}^{4} & Σ {xi}^{3} {yi}^{2} & Σ {yi}^{5} \\ Σ {xi}^{3} & Σ {xi}^{4} & Σ {xi}^{3} yi & Σ {xi}^{5} & Σ {xi}^{3} {yi}^{2} & Σ {xi}^{6} & Σ {xi}^{3} {yi}^{3} \\ Σ {yi}^{3} & Σ {xiyi}^{3} & Σ {yi}^{4} & Σ {xi}^{2} {yi}^{3} & Σ {yi}^{5} & Σ {xi}^{3} {yi}^{3} & Σ {yi}^{6}\end{matrix} ] [ \begin{matrix}{k}_{1} \\ {k}_{3} \\ {k}_{5} \\ {k}_{7} \\ {k}_{11} \\ {k}_{13} \\ {k}_{19}\end{matrix} ] = [ \begin{matrix}Σ dxi \\ Σ dxixi \\ Σ dxiyi \\ Σ {dxixi}^{2} \\ Σ {dxiyi}^{2} \\ Σ {dxixi}^{3} \\ Σ {dxiyi}^{3}\end{matrix} ] \\ [ \begin{matrix}Σ1 & Σ xi & Σ yi & Σ {xi}^{2} \\ Σ xi & Σ {xi}^{2} & Σ xiyi & Σ {xi}^{3} \\ Σ yi & Σ xiyi & Σ {yi}^{2} & Σ {xi}^{2} yi \\ Σ {xi}^{2} & Σ {xi}^{3} & Σ {xi}^{2} yi & Σ {xi}^{3}\end{matrix} ] [ \begin{matrix}{k}_{2} \\ {k}_{6} \\ {k}_{4} \\ {k}_{12}\end{matrix} ] = [ \begin{matrix}Σ dyi \\ Σ dyixi \\ Σ dyiyi \\ Σ {dyixi}^{2}\end{matrix} ] \\ ( here , Σ = {\sum }_{k = 1}^{m} ) \qquad ( 3 )$$

Examples of the solution of the normal equation shown by (3) include an LU solution and a sweep-out method.

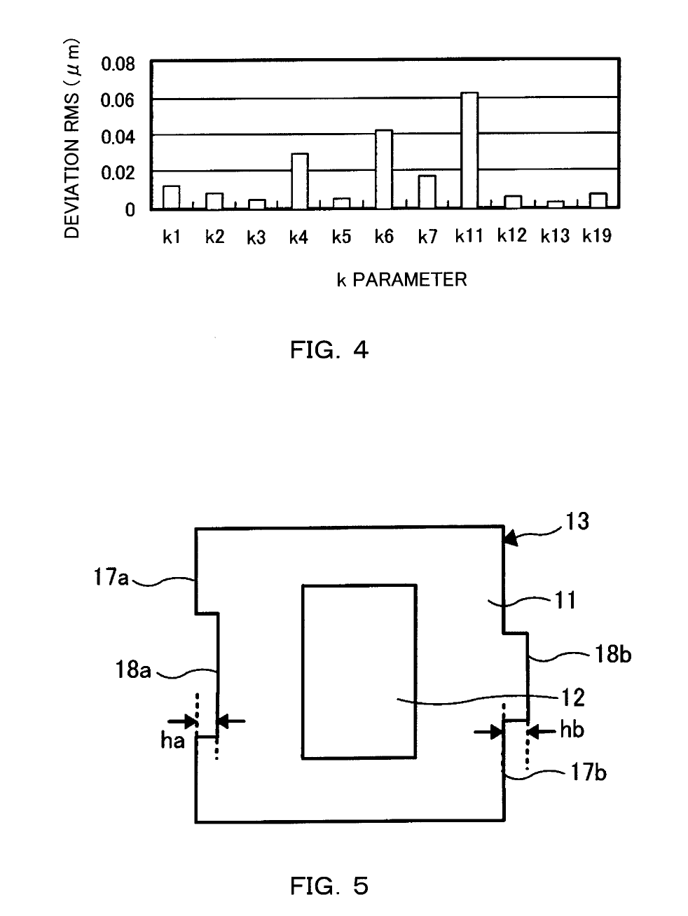

When the pattern positional error correction coefficient is calculated for the pattern positional accuracy shown in FIG. 3 according to the equation (3), the respective correction coefficients are calculated as shown in FIG. 4. In FIG. 4, an axis of abscissa represents the respective correction coefficients (k parameters) of the correction equation, while an axis of ordinate represents the positional deviation amount corresponding to the respective k parameters. When the result shown in FIG. 4 is calculated, it is found that the major factor of the pattern positional accuracy is the positional deviation of the component of the correction coefficient k11, i.e., the positional deviation of the arched component with respect to the y axis. Accordingly, the pattern positional accuracy of the pattern formed on the template 13 can be corrected by correcting the positional deviation of the arched component with respect to the y axis, which is the component of the correction coefficient k11.

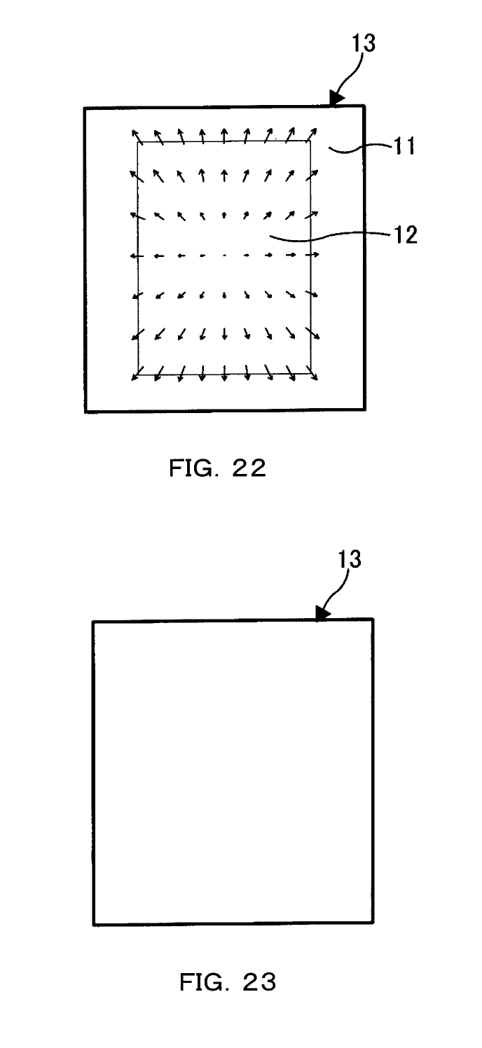

FIGS. 22 to 37 respectively show the relationship between the k parameters, other than the component of the correction coefficient k11, indicating the positional deviation components of the high-order components (non-linear components) and the corresponding vector map. In the following description, a case in which the major factor of the pattern positional accuracy is defined as the component of the correction coefficient k11, i.e., the positional deviation component corresponding to the maximum correction coefficient, is defined as the major factor of the pattern positional accuracy, and the major factor is corrected will be described. However, not only the maximum correction coefficient but also the positional deviation components corresponding to a plurality of correction coefficients not less than respective predetermined values may be defined as the major factors of the pattern positional accuracy.

Next, the outer shape of the template 13 is determined on the basis of the calculated pattern positional error correction coefficient, so that a template outer correction amount is calculated (step S103). The outer shape of the template 13 is determined such that, when the template 13 is clamped by a clamp pin 16 of a imprint apparatus as described later with reference to FIG. 9, stress is applied to the component that is the major factor of the pattern positional accuracy in the direction of canceling the major factor of the pattern positional accuracy.

For example, when it is found that the major factor of the pattern positional accuracy is the component of the correction coefficient k11 as shown in FIG. 4, the outer shape of the template 13 is determined to be a shape having a concave at a side face 17a of four side faces 17, which is orthogonal to the direction opposite to the vector shown in FIG. 3, and a convex at a side face 17b of four side faces 17 facing the side face 17a. More specifically, the shape of the template 13 is determined to be the shape having the concave 18a at the central portion of the side face 17a and the convex 18b at the central portion of the side face 17b.

In the calculation of the outer shape correction amount of the template 13, a value by which stress, having a magnitude of canceling the major factor of the pattern positional accuracy, is applied is calculated on the basis of the determined shape of the template 13, the material of the template 13, and a magnitude of the pressure applied by the clamp pin 16.

For example, when the pattern positional error correction coefficient that is the equation of (correction coefficient k11)=0.05 (PPM) is calculated, the outer shape of the template 13 as shown in FIG. 5 is determined. The depth ha of the concave 18a and the height hb of the convex 18b are calculated to be both 500 μm on the basis of the determined shape, the material of the template 13, and the magnitude of the pressure applied by the clamp pin 16.

Next, the side faces 17 of the template 13 are processed to have desired concave and convex shapes on the basis of the determined shape of the template 13 and the calculated outer shape correction amount of the template, whereby the template 13 is formed (step S104). The template 13 described above is processed as described below.

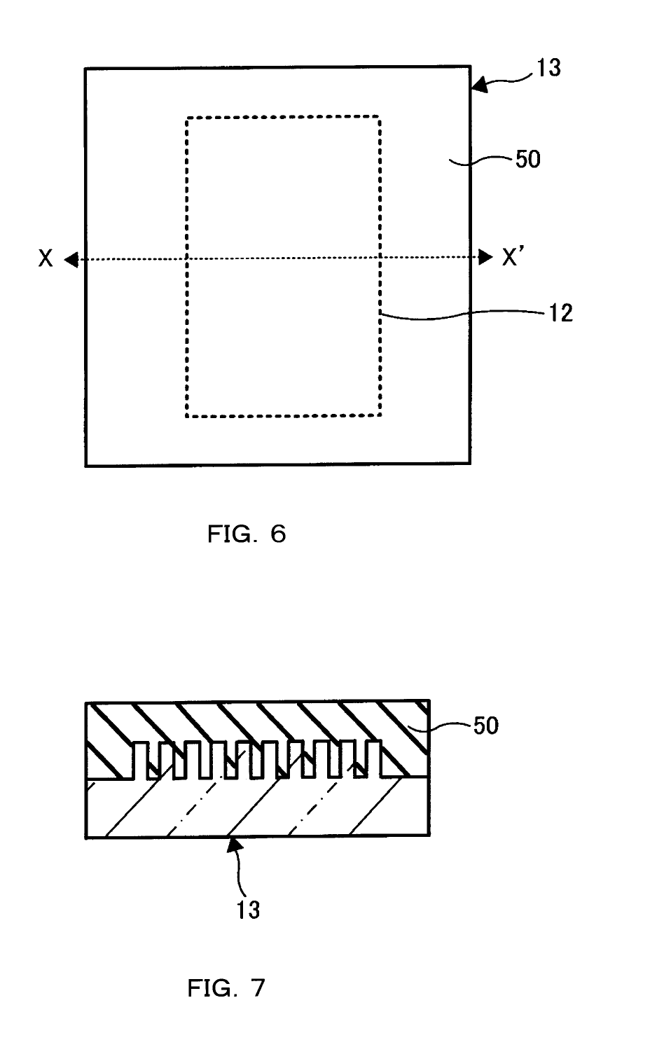

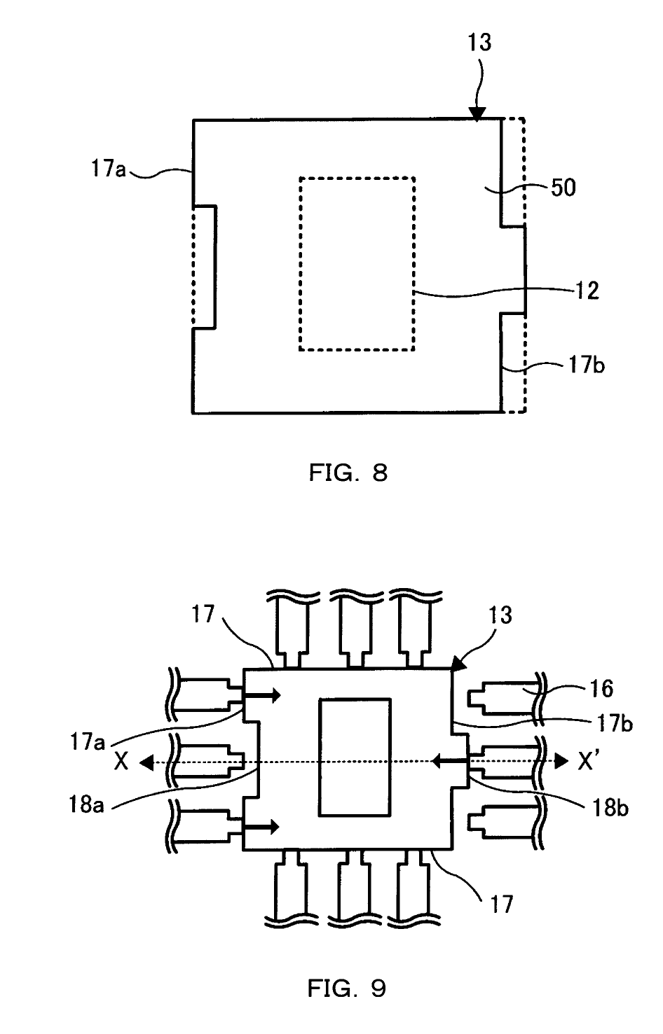

A protection film 50 is first applied on the entire surface of the template 13 as shown in FIG. 6 and FIG. 7 that is a sectional view taken along a broken line X-X′ in FIG. 6.

Then, the side faces 17a and 17b of the template 13 are ground so as to form the template 13 as shown in FIG. 5 with the protection film 50 applied onto the surface as shown in FIG. 6.

Finally, the protection film 50 is removed, and then, the surface of the template 13 is rinsed with sulfur hydrogen peroxide solution, and further rinsed with pure water.

Thus, the template 13 is processed.

The template for the imprint process is formed according to the steps S101 to S104 shown in FIG. 1.

The imprint process using the template 13 that is formed by the process of forming an imprint-template described above will be described with reference to the flowchart in FIG. 1 and FIGS. 9 to 15.

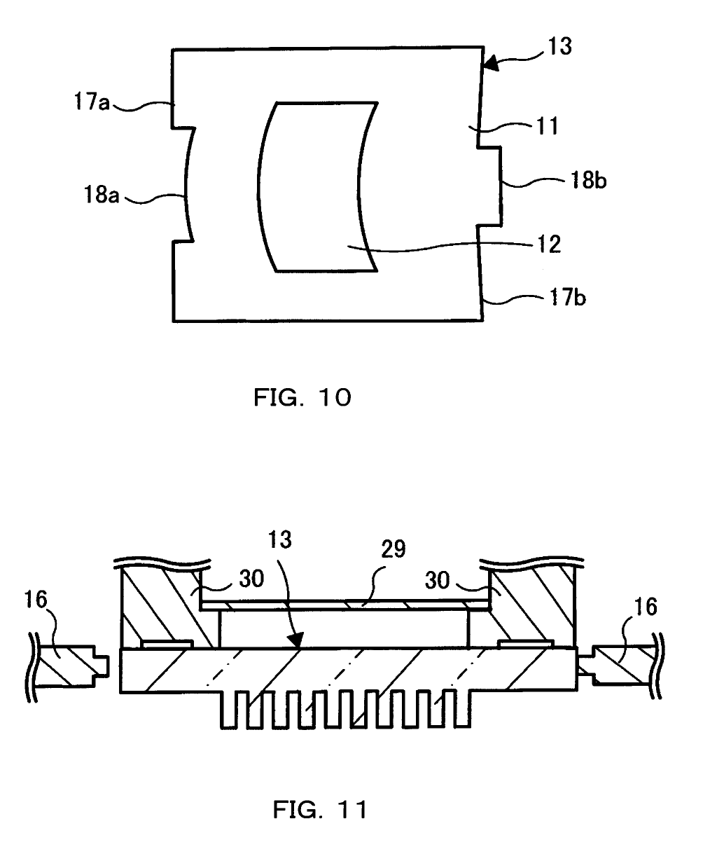

Firstly, the template 13 formed by the processes at steps S101 to S104 in FIG. 1 is clamped by clamp pins 16 attached to an imprint apparatus so as to apply pressure to the four side faces 17 as shown in FIG. 9 (step S105). In this process, even if the pressures applied to the template 13 by the clamp pins 16 are controlled to be equal to one another, pressure greater than the pressure applied to the other portions is applied to the portion of the side face 17a other than the concave 18a and to the convex 18b of the side face 17b of the template 13. The clamp pins 16 are in contact with the concave 18a at the side face 17a and the portion other than the convex 18b at the side face 17b of the template 13. However, the pressure applied to the concave 18a at the side face 17a and the portion other than the convex 18b at the side face 17b of the template 13 is smaller than the pressure applied to the portion other than the concave 18a at the side face 17a and to the convex 18b at the side face 17b of the template 13. Accordingly, the template 13 is distorted like an arch as shown in FIG. 10, so that the major component of the pattern positional deviation amount is corrected.

If the template 13 is clamped with stability, the clamp pins 16 do not have to be in contact with the concave 18a at the side face 17a and with the portion other than the convex 18b at the side face 17b of the template 13.

When the template 13 is clamped, the template 13 is clamped by the clamp pins 16, and at the same time, the template 13 is sucked by a suction pipe 30 provided at a side portion of a window 29 in the imprint apparatus as shown in FIG. 11 that is a sectional view taken along a broken line X-X′ in FIG. 9, whereby the template 13 is mounted in the imprint apparatus.

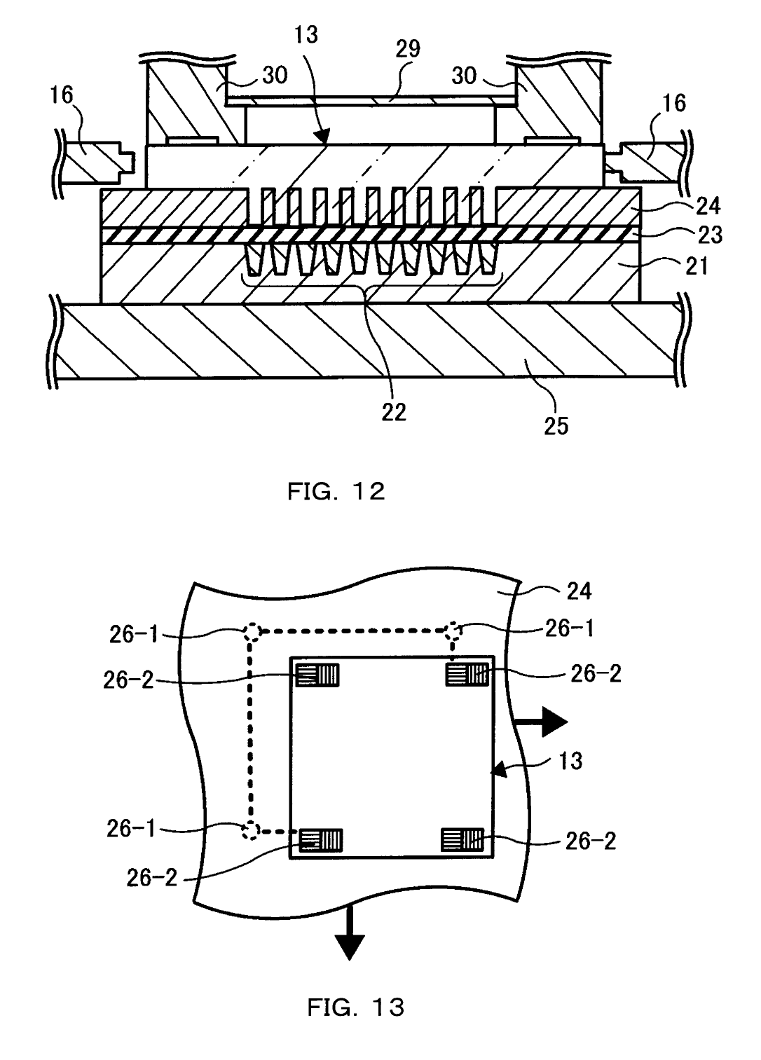

As shown in FIG. 12, a resist 24, which is a resin layer (transfer layer) on which the pattern formed on the template 13 is transferred, is applied onto a pattern 22 (base pattern 22) that has already been formed on the surface of the wafer (semiconductor substrate) 21 via an oxide film 23. The template 13 in which the major factor of the pattern positional accuracy is corrected is pressed against the resist 24. The position in the x direction and the position in the y direction of the template 13 are corrected in this state by moving the stage 25 on which the wafer 21 is placed in the imprint apparatus (step S106).

The position of the template 13 is corrected in such a manner that the stage 25 is moved in the directions indicated by arrows in FIG. 13 so as to allow first reference marks 26-1 that are formed at four corners of the wafer 21 for each shot position (the position where the template 13 is pressed) indicating the reference positions of the template 13 and reference marks 26-2 formed at four corners of the template 13 to overlap with each other, as shown in FIG. 13.

Next, the resist 24 is hardened through the irradiation of the resist 24 with ultraviolet ray (step S107).

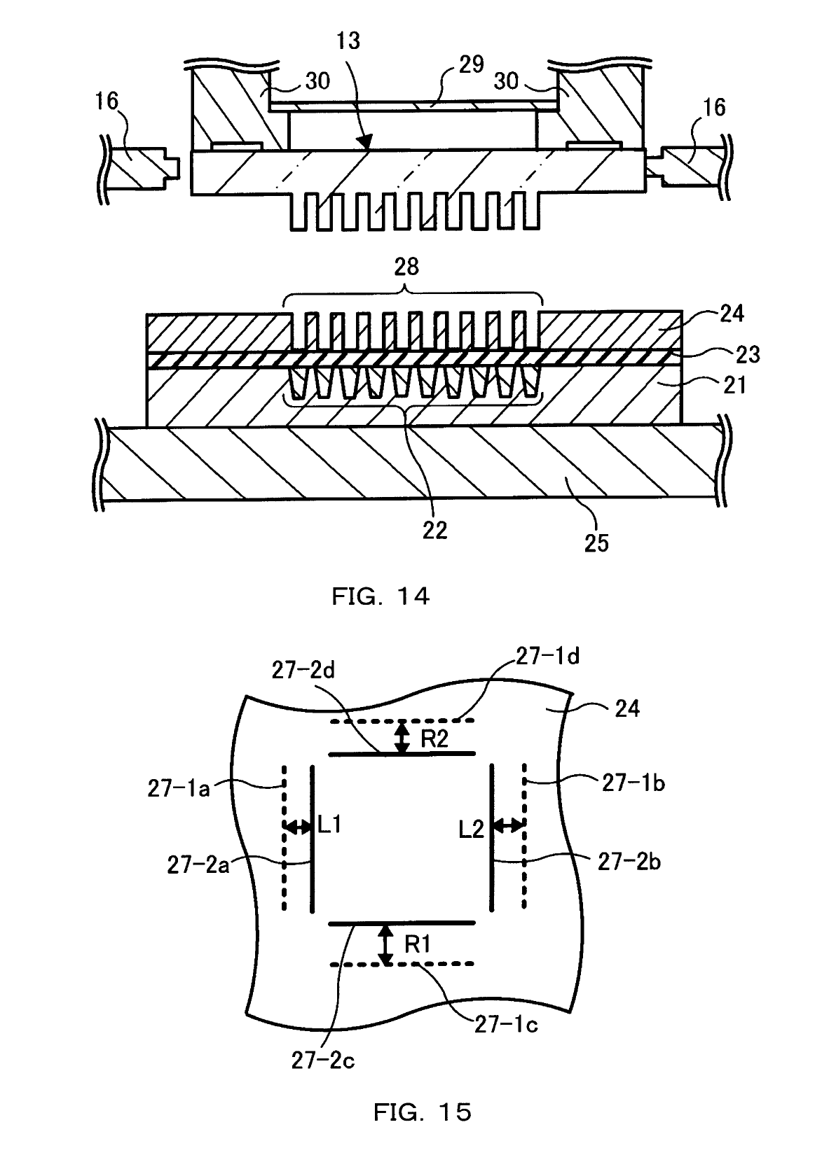

Then, as shown in FIG. 14, the template 13 is removed from the hardened resist 24, whereby the pattern 28 in which the major factor of the pattern positional accuracy is corrected is formed on the resist 24 (step S108).

Finally, the alignment accuracy at the shot positions is examined using an alignment accuracy testing apparatus in the state where the pattern 28 is formed on the resist 24. Accordingly, the relative positional deviation of the pattern 28 formed on the resist 24 with respect to the base pattern 22 is evaluated (step S109).

The alignment accuracy means the relative positional deviation between the actual shot position and the reference shot position. The relative positional deviation is evaluated, as shown in FIG. 15, by using a first box-like mark 27-1 formed on the wafer 21 beforehand and a second box-like mark 27-2 imprinted on the resist 24 by the template 13.

Specifically, when a positional deviation amount between the left side 27-1a of the first box-like mark and the left side 27-2a of the second box-like mark is defined as L1, a positional deviation amount between the right side 27-1b of the first box-like mark and the right side 27-2b of the second box-like mark is defined as L2, a positional deviation amount between the bottom side 27-1c of the first box-like mark and the bottom side 27-2c of the second box-like mark is defined as R1, and a positional deviation amount between the top side 27-1d of the first box-like mark and the top side 27-2d of the second box-like mark is defined as R2, the alignment accuracy (Δx, Δy) is obtained from the equation (4) below.

Δx=(L2−L1)/2

Δy=(R2−R1)/2 (4)

As described above, the relative positional deviation of the pattern 28 formed on the resist 24 with respect to the base pattern 22 is evaluated by detecting the alignment accuracy. If the relative positional deviation falls within a specified range as a result of the evaluation of the relative positional deviation, the imprint process is completed. On the contrary, if the relative positional deviation is outside the specified range, the above-mentioned relative positional deviation is detected so as to calculate the correction coefficient (hereinafter referred to as alignment error correction coefficient) for correcting the deviation, and the processes at the steps S103 to S109 shown in FIG. 1 are repeated on the basis of the calculated correction coefficient until the alignment accuracy falls within the specified range.

According to the processes at the steps S101 to S109 shown in FIG. 1, the desired pattern is formed on the resist 24 with the pattern positional accuracy of the template 13 being corrected.

In the imprint process in the process at the steps S105 to S109 shown in FIG. 1, the wafer 21 on which the pattern is actually formed may be used as described above, and a test wafer on which the same pattern 22 as that formed on the wafer 21 is formed may be used.

As described above, according to the imprint process of the first embodiment, the template 13 is formed in such a manner that the positional accuracy of the pattern formed on the template 13 is corrected by the process of forming the imprint-template shown in the steps S101 to S104 in FIG. 1 when the template 13 is clamped. Therefore, the positional accuracy of the pattern formed on the template 13 is corrected in the imprint process shown in the steps S105 to S109 in FIG. 1 when the template 13 is clamped. Thus, the alignment accuracy of the pattern can be enhanced.

### Second Embodiment

Next, a method of manufacturing a semiconductor device according to a second embodiment of the invention will be described.

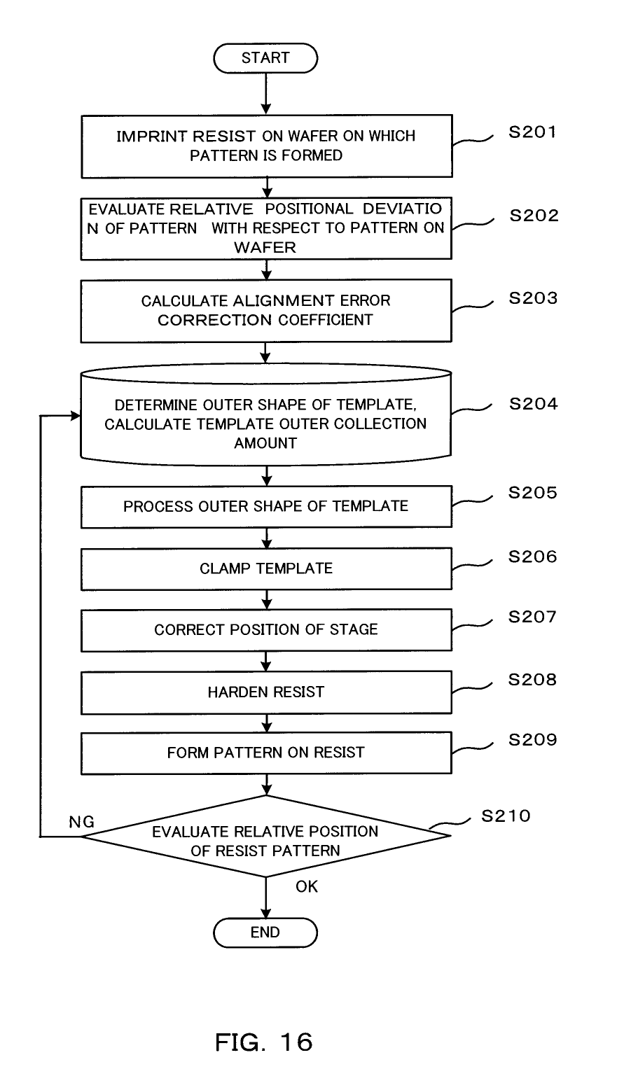

FIG. 16 is a flowchart used to describe the method of manufacturing a semiconductor device according to the second embodiment. The method of manufacturing a semiconductor device shown in FIG. 16 also includes a process of forming a template to process the imprint-template into a desired outer shape, and an imprint process using the formed template. Since the process of forming a template in the method of manufacturing a semiconductor device of the second embodiment is different from the method of manufacturing a semiconductor device according to the first embodiment, the process of forming a template will mainly be described below.

In the process of forming a template in the second embodiment, a pattern including a position evaluating mark is formed on the central portion 12 of the glass substrate by means of an electron beam lithography and etching, whereby a template is formed. The same imprint process as that in the steps S105 to S109 in the first embodiment is performed by using the formed template (step S201).

In the process at step S201, the wafer 21 on which the pattern is actually formed may be used as described above, and a test wafer on which the same pattern 22 as that formed on the wafer 21 is formed may be used, as is explained in the first embodiment.

Next, the relative positional deviation of the pattern of the resist formed in the process at the step S201 with respect to the pattern (base pattern) on the surface of the wafer is evaluated (step S202). This process is carried out in the same manner as that in the step S109 in the first embodiment. Specifically, the position of the base pattern is defined as the reference position of the pattern formed on the resist, and the same evaluation as that in the step S109 in the first embodiment is carried out.

After the relative positional deviation is evaluated as described above, the positional deviation is calculated on the basis of the result of the evaluation of the relative positional deviation so as to detect the relative positional deviation, and the alignment error correction coefficient is calculated (step S203), as in the steps S102 to S104 described in the first embodiment. Subsequently, the outer shape of the template is determined on the basis of the calculated alignment error correction coefficient, whereby the template outer shape correction amount is calculated (step S204). Then, the outer shape of the template is processed on the basis of the outer shape correction amount (step S205).

According to the processes at the steps S201 to 205, the imprint-template is formed.

Since the imprint process shown in the steps S206 to S210 in FIG. 16 is the same as the process in the steps S105 to S109 described in the first embodiment, the description of the imprint process will not be repeated.

As described above, according to the method of manufacturing a semiconductor device of the second embodiment, the template is formed in such a manner that the positional accuracy of the pattern formed on the template is corrected by the process of forming the imprint-template shown in the steps S201 to S205 when the template is clamped. Therefore, the positional accuracy of the pattern formed on the template is corrected in the imprint process shown in the steps S206 to S210 when the template 13 is clamped. Thus, the alignment accuracy of the pattern can be enhanced.

### Third Embodiment

Next, a method of manufacturing a semiconductor device according to a third embodiment of the invention will be described.

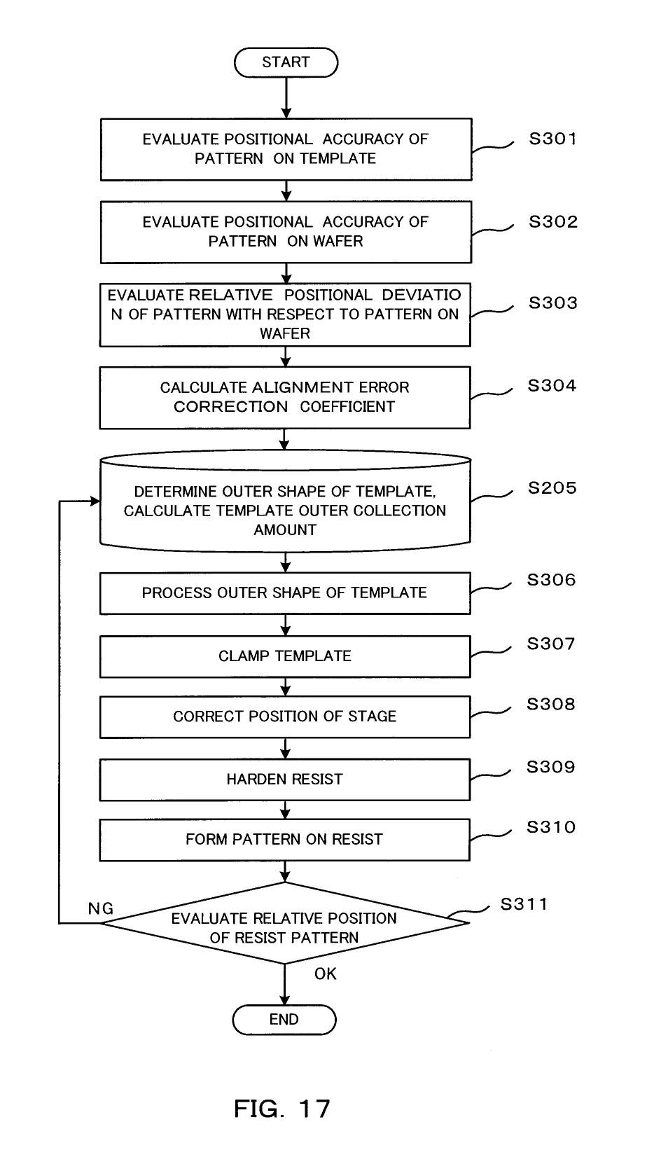

FIG. 17 is a flowchart used to describe the method of manufacturing a semiconductor device according to the third embodiment. The method of manufacturing a semiconductor device shown in FIG. 17 is also includes a process of forming a template to process the imprint-template into a desired outer shape, and an imprint process using the formed template. Since the process of forming a template in the method of manufacturing a semiconductor device of the third embodiment is different from the method of manufacturing a semiconductor device according to the first and second embodiments, the process of forming a template will mainly be described below.

In the process of forming a template according to the third embodiment, the pattern positional accuracy of the same template as the template used in the first and second embodiments is evaluated in the same manner as in the step S101 in the first embodiment using an absolute position measuring apparatus that is separate from the imprint apparatus (step S301).

Next, the pattern positional accuracy of the pattern (base pattern) on the surface of the wafer is evaluated by the absolute position measuring apparatus (step S302). The pattern positional accuracy of the base pattern 22 is evaluated in the same manner as in the step S301.

The process in the step S301 and the process in the step S302 are not necessarily performed in this order. The process in the step S301 and the process in the step S302 may be performed in the reverse order.

Subsequently, the relative positional deviation of the position evaluating mark formed on the template with respect to the position evaluating mark on the surface of the wafer, or the relative positional deviation of the pattern formed on the template with respect to the pattern on the surface of the wafer, is evaluated from the data obtained respectively by the evaluation of the pattern positional accuracy of the template and the evaluation of the pattern positional accuracy of the base pattern (step S303). Specifically, the position of the base pattern is defined as the reference position, and the relative positional deviation of the pattern formed on the template from the reference position is evaluated.

After the relative positional deviation is evaluated as described above, the positional deviation is calculated on the basis of the result of the evaluation of the relative positional deviation so as to detect the relative positional deviation, and the alignment error correction coefficient is calculated (step S304), as in the steps S102 to S104 described in the first embodiment. Subsequently, the outer shape of the template 13 is determined on the basis of the calculated alignment error correction coefficient, whereby the template outer shape correction amount is calculated (step S305). Then, the outer shape of the template 13 is processed on the basis of the outer shape correction amount (step S306).

According to the process at the steps S301 to S306, the imprint-template is formed.

The imprint process shown by the steps S307 to S311 in FIG. 17 is the same as the process in the steps S105 to S109 described in the first embodiment, and thus the description of the imprint process will not be repeated.

As described above, according to the imprint process of the third embodiment, the template is formed in such a manner that the positional accuracy of the pattern formed on the template is corrected by the process of forming the imprint-template shown in the steps S301 to S306 when the template is clamped. Therefore, the positional accuracy of the pattern formed on the template is corrected in the imprint process shown in the steps S307 to S311 when the template 13 is clamped. Thus, the alignment accuracy of the pattern can be enhanced.

In the respective embodiments described above, the template 13 is formed to have appropriate concave and convex at the side faces 17a and 17b of the template 13 in order to distort the template 13 in the direction opposite to the direction of the vector indicated in the vector map in FIG. 3. However, the concave and convex are not necessarily formed on the side faces 17. The template 13 can similarly be distorted by forming the concave and convex in the plane of the template 13 or at the peripheral edge (in the front surface, in the back surface, or four side faces 17) of the template 13.

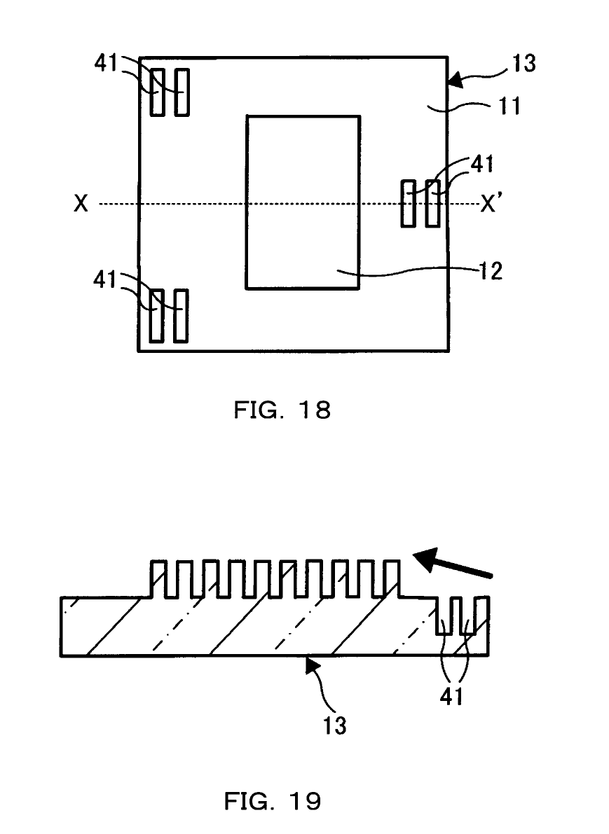

For example, when the vector map shown in FIG. 3 is calculated, grooves 41 may be formed at the upper-left portion, lower-left portion, and central portion at the right side from the front surface toward the back surface of the template 13 as shown in FIG. 18. When the template 13 formed with the grooves 41 is clamped, the template 13 is distorted in the direction indicated by an arrow shown in FIG. 19 that is a sectional view taken along a line X-X′ in FIG. 18. The pattern positional accuracy of the pattern on the template 13 can be corrected with the distortion described above.

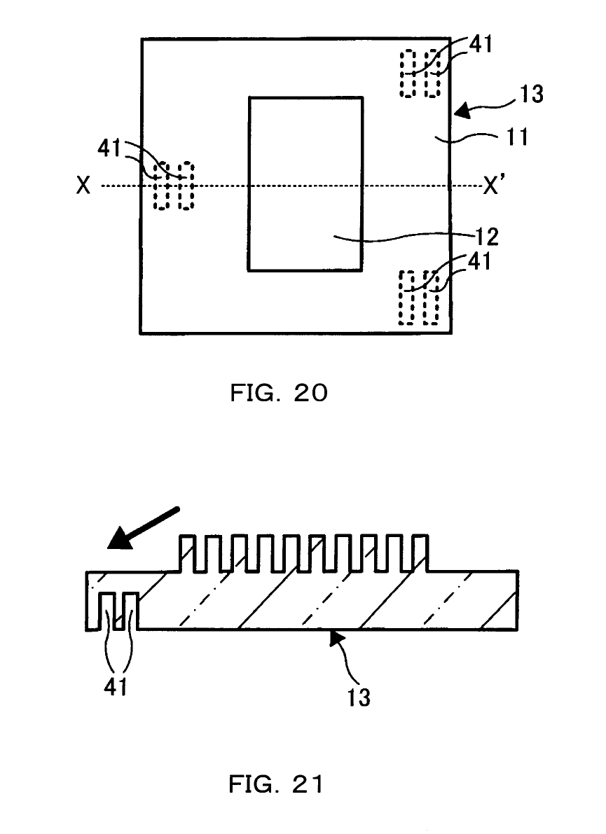

Further, the grooves 41 may be formed at the upper-right portion, lower-right portion, and central portion at the left side from the back surface toward the front surface of the template 13 as shown in FIG. 20. When the template 13 formed with the grooves 41 is clamped, the template 13 is distorted in the direction indicated by an arrow shown in FIG. 21 that is a sectional view taken along a line X-X′ in FIG. 20. The pattern positional accuracy of the pattern on the template 13 can be corrected with the distortion described above.

As described above, the template 13 is processed to have appropriate concave and convex on any of the side faces 17, front surface, and back surface of the template 13, whereby the pattern positional accuracy of the pattern on the template 13 can be corrected.

Even if the vector map indicating the pattern positional accuracy is not the one shown in FIG. 3, the pattern positional accuracy can be corrected by appropriately processing the shape of the template 13 according to the process of forming a template and the imprint process of the invention. Other vector maps indicating the pattern positional accuracy and the shape of the template 13 that can correct the pattern positional accuracy corresponding to the vector map will be described below.

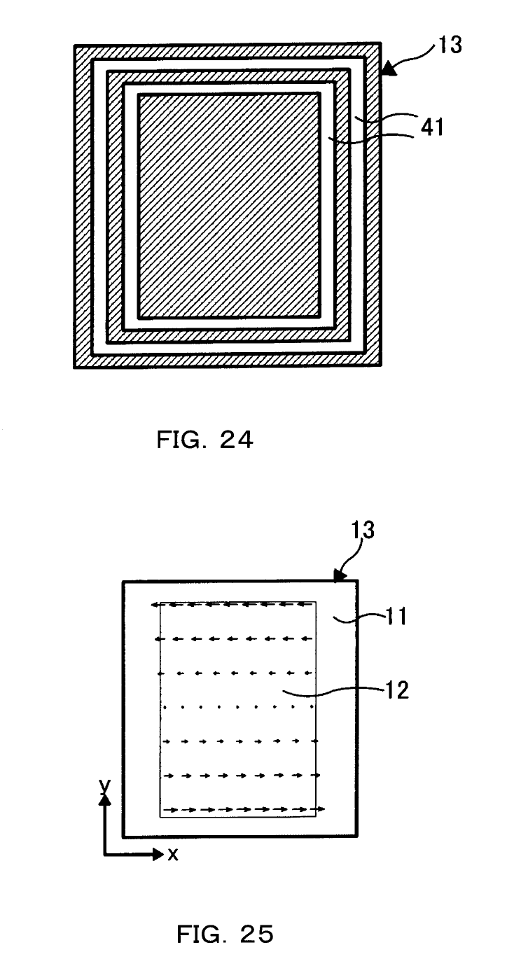

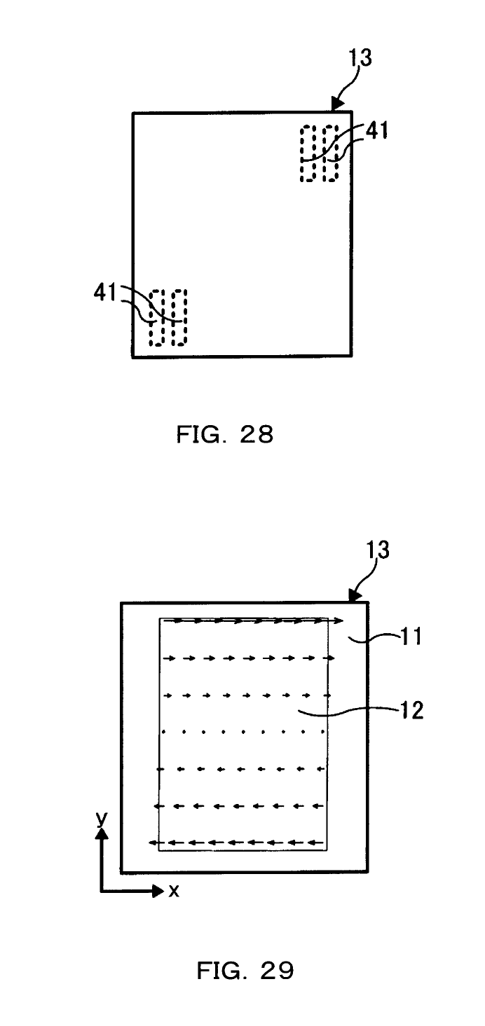

FIGS. 22, 25, 29, 33, and 37 respectively show vector maps indicating the pattern positional accuracy. FIGS. 23, 26, 30, 34, and 38 show the outer shapes of the template 13 that can correct the pattern positional accuracy by processing the side faces 17 of the template 13 according to the respective vector maps. FIGS. 24, 27, 31, 35, and 39 show the outer shapes of the template 13 that can correct the pattern positional accuracy by processing the front surface according to the respective vector maps. When the vector maps shown in FIGS. 25, 29, 33, and 37 are calculated, the pattern positional accuracy can be corrected by processing the back surface of the template 13. These cases are shown in FIGS. 28, 32, 36, and 40, respectively. FIGS. 23, 24, 26, 27, 28, 30, 31, 32, 34, 35, 36, 38, 39, and 40 only show the outer shapes of the template 13.

FIG. 22 shows the vector map when the pattern on the template 13 is greater than the pattern 22 on the surface of the wafer. In the case of the vector map shown in FIG. 22, k2 and k3 of the correction coefficients are calculated to be the greatest values. In this case, it is unnecessary to process the side faces 17 of the template 13 as shown in FIG. 23 and instead, the template 13 may be compressed so as to have the desired size when the template 13 is clamped. Alternatively, the grooves 41 may be formed on the front surface of the template 13 along the periphery of the template 13 as shown in FIG. 24.

When the vector map shown in FIG. 22 is calculated, the pattern positional accuracy cannot be corrected only by processing the back surface of the template 13.

When the grooves 41 are formed on the front surface of the template 13 as described above, the grooves 41 may be formed by dry etching or wet etching. The grooves 41, described later, formed on the template 13 may also be formed by dry etching or wet etching.

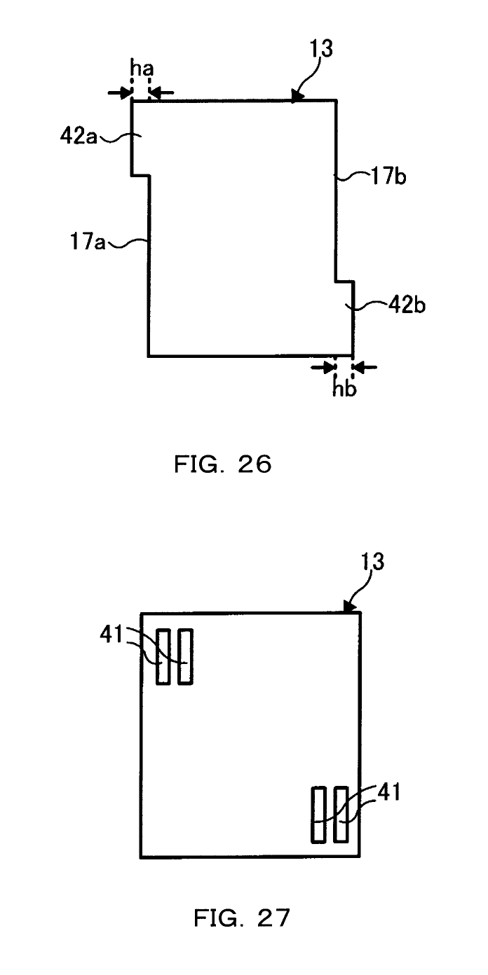

FIG. 25 shows a vector map in which the positional deviation becomes larger in the −x direction toward the upper side of the figure, while the positional deviation becomes larger in the x direction toward the lower side of the figure, in the pattern formed on the template 13. In FIG. 25, the ratio of the positional deviations at the upper side and the lower side are substantially equal to each other. In the case of the vector map in FIG. 25, the value of k6−k5 is calculated to be the greatest value among the correction coefficients. In this case, the pattern positional accuracy can be corrected by processing the side faces 17a and 17b of the side faces 17 of the template 13 orthogonal to the x axis as shown in FIG. 26. Specifically, a convex 42a is formed at the side face 17a at the upper side of the figure in order to correct the positional deviation in the −x direction. Further, a convex 42b is formed at the side face 17b at the lower side of the figure in order to correct the positional deviation in the x direction. The height ha of the convex 42a and the height hb of the convex 42b are substantially equal to each other. Alternatively, grooves 41 may be formed at the upper-left portion and lower-right portion in the figure from the front surface toward the back surface of the template 13 as shown in FIG. 27. Further, grooves 41 may be formed at the upper-right portion and lower-left portion in the figure from the back surface toward the front surface of the template 13 as shown in FIG. 28. The grooves 41 formed at the upper-left portion and lower-right portion in FIG. 27 are formed to have substantially the same depth. The same is true for FIG. 28.

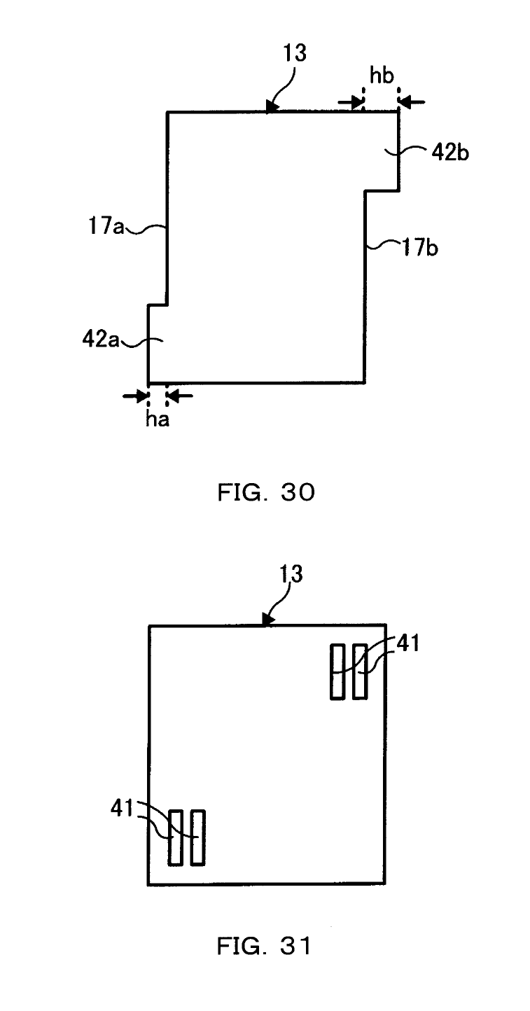

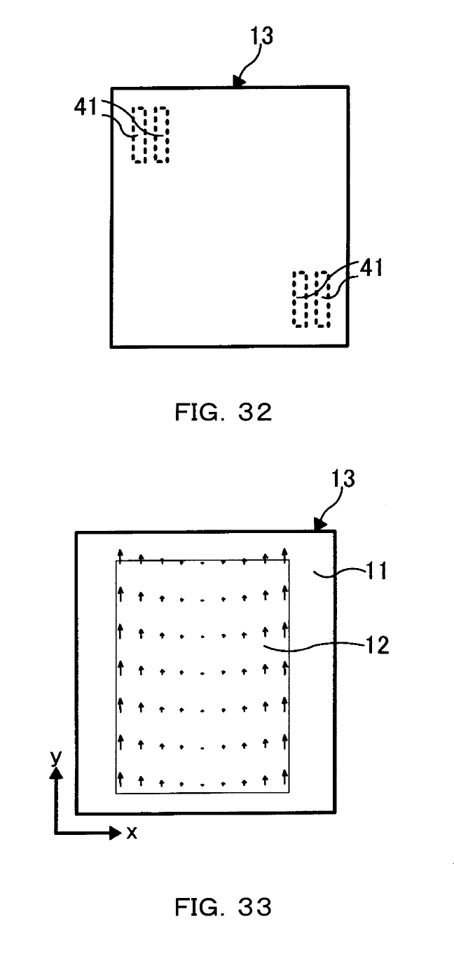

FIG. 29 shows a vector map in which the positional deviation becomes larger in the x direction toward the upper side in the figure, while the positional deviation becomes larger in the −x direction toward the lower side of the figure, in the pattern formed on the template 13. In FIG. 29, the positional deviation in the x direction is greater than the positional deviation in the −x direction. In the case of the vector map in FIG. 29, the value of k19 is calculated to be the greatest value among the correction coefficients. In this case, the pattern positional accuracy can be corrected by processing the side faces 17a and 17b of the side faces 17 of the template 13 orthogonal to the x axis as shown in FIG. 30. Specifically, the convex 42b is formed at the side face 17b at the upper side of the figure in order to correct the positional deviation in the x direction. Further, the convex 42a is formed at the side face 17a at the lower side of the figure in order to correct the positional deviation in the −x direction. The height hb of the convex 42b is formed to be greater than the height ha of the convex 42a. Alternatively, grooves 41 may be formed at the upper-right portion and lower-left portion in the figure from the front surface toward the back surface of the template 13 as shown in FIG. 31. Further, grooves 41 may be formed at the upper-left portion and lower-right portion in the figure from the back surface toward the front surface of the template 13 as shown in FIG. 32. The groove 41 formed at the upper-right portion is formed to have the depth greater than the depth of the groove 41 formed at the lower-left portion in FIG. 31. The groove 41 formed at the upper-left portion is formed to have the depth greater than the depth of the groove 41 formed at the lower-right portion in FIG. 32.

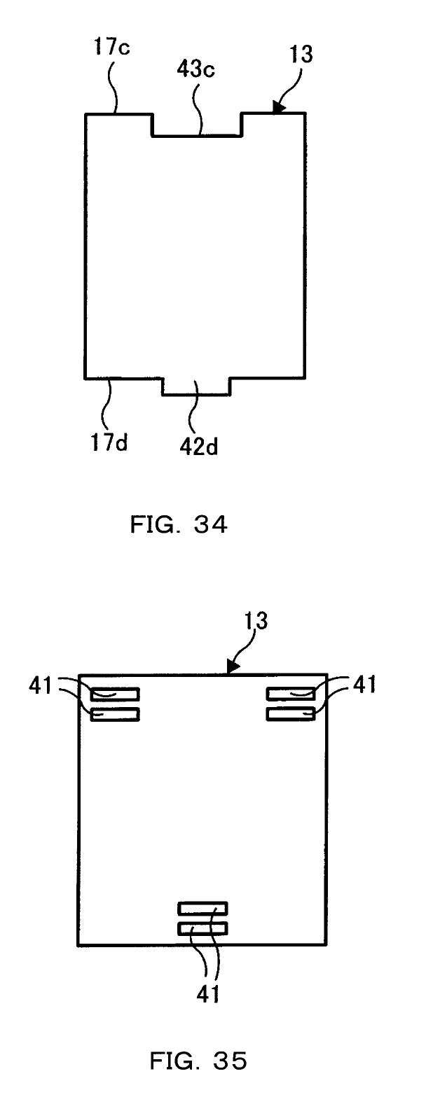

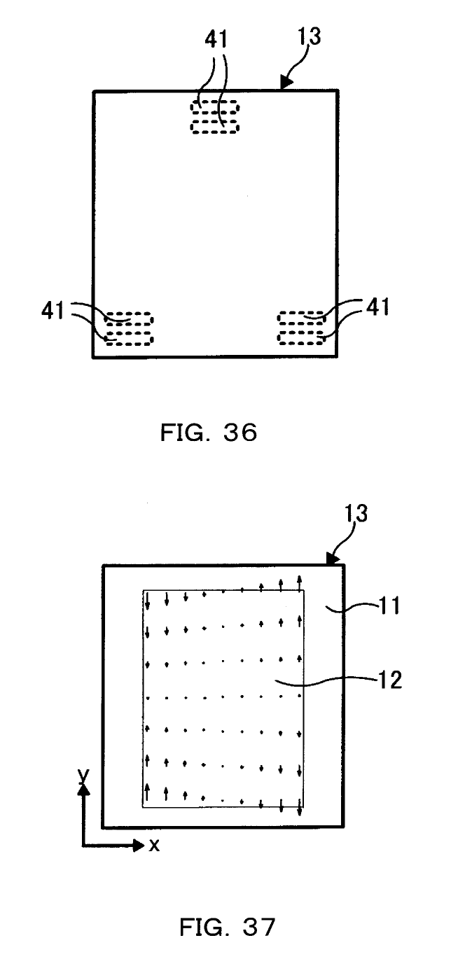

FIG. 33 shows a vector map in which the positional deviation becomes larger in the y direction toward the right side in the figure or toward the left side in the figure, in the pattern formed on the template 13. In the case of the vector map in FIG. 33, the value of k12 is calculated to be the greatest value among the correction coefficients. In this case, the pattern positional accuracy can be corrected by processing the side faces 17c and 17d of the side faces 17 of the template 13 orthogonal to the y axis as shown in FIG. 34. Specifically, a concave 43c is formed at the central portion of the side face 17c, and a convex 42d is formed at the central portion of the side face 17b. Alternatively, grooves 41 may be formed at the upper-right portion, upper-left portion, and the central portion at the lower side in the figure from the front surface toward the back surface of the template 13 as shown in FIG. 35. Further, grooves 41 may be formed at the lower-left portion, lower-right portion, and the central portion at the upper side in the figure from the back surface toward the front surface of the template 13 as shown in FIG. 36.

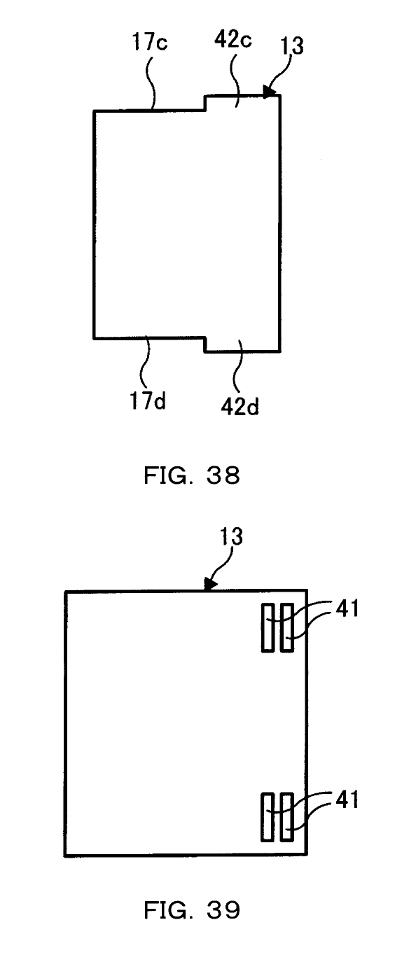

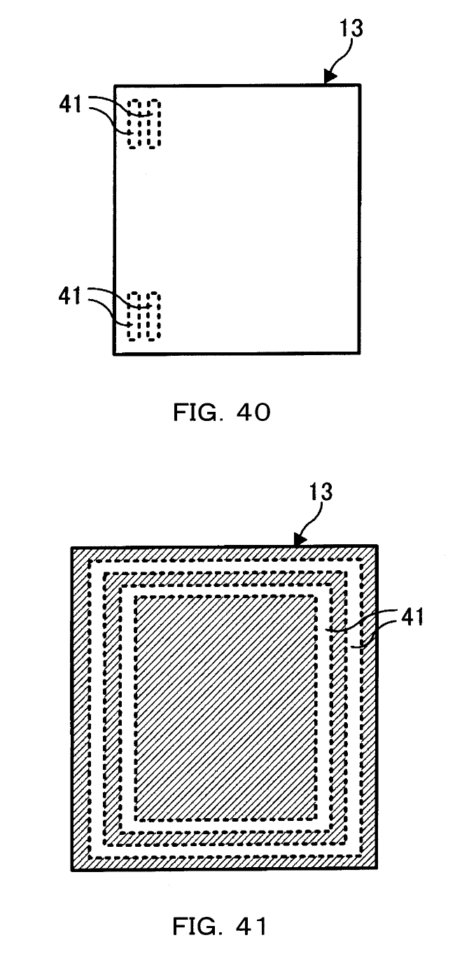

FIG. 37 shows a vector map in which, at the upper side in the figure, the positional deviation becomes larger in the −y direction toward the left side in the figure, and the positional deviation becomes larger in the y direction toward the right side in the figure, while at the lower side in the figure, the positional deviation becomes larger in the y direction toward the left side in the figure, and the positional deviation becomes larger in the −y direction toward the right side in the figure, in the pattern formed on the template 13. In the case of the vector map in FIG. 37, the value of k10 is calculated to be the greatest value among the correction coefficients. In this case, the pattern positional accuracy can be corrected by processing the side faces 17c and 17d of the side faces 17 of the template 13 orthogonal to the y axis as shown in FIG. 38. Specifically, convexes 42c, 42d are formed at the side faces 17c, 17d at the right side in the figure. Alternatively, grooves 41 may be formed at the upper-right portion and lower-right portion in the figure from the front surface toward the back surface of the template 13 as shown in FIG. 39. Further, grooves 41 may be formed at the upper-left portion and lower-left portion in the figure from the back surface toward the front surface of the template 13 as shown in FIG. 40.

The examples of the vector map indicating the positional deviation of the pattern and the examples of the outer shape of the template 13 that can correct the pattern positional accuracy corresponding to each example are described above. Although not shown in FIGS. 22, 25, 29, 33, and 37, the pattern positional accuracy can also be corrected even if the vector map in which the pattern on the template 13 is smaller than the pattern 22 on the surface of the wafer is calculated. Specifically, as shown in FIG. 41, grooves 41 may be formed on the back surface of the template along the periphery of the template 13, whereby the pattern on the template 13 can be enlarged and imprinted.

The process described above is such that the positional deviation of the pattern formed on the template 13 is detected, the correction coefficient for correcting the positional deviation using the equations 1 to 3 is calculated from the positional deviation, and the outer shape of the template 13 is appropriately processed so as to correct the pattern positional deviation from the calculated correction coefficient.

However, in the invention, the template 13 may appropriately be processed so as to apply the pressure in the direction opposite to the direction of the vector indicated in the vector map as in FIG. 3 when the template 13 is clamped. Accordingly, the invention can apply various processes that can process the template 13 as described above, and the equations 1 to 3 are not necessarily used.

The process of an imprint-template according to the invention and the imprint process using the template formed by the process have been described above. However, the embodiment of the invention is not limited to those described above.

For example, the side faces 17, the front surface, or the back surface of the template 13, or some of these faces may be appropriately processed considering the number of the clamp pins 16, whereby various pattern positional accuracies can be corrected.

The invention is applicable to the case in which an imprint apparatus that clamps the respective side faces 17 of the template 13 with a plurality of clamp pins 16 is used. The number of the clamp pins 16 to one side face is not limited to three. Although the pressure applied by the clamp pins 16 to the template 13 is fixed in the above-mentioned embodiments, the pattern positional accuracy may be corrected by adjusting the pressure applied by the clamp pins 16 in addition to the processing of the outer shape of the template 13.

A master may be used for the template 13, or a duplicate that is duplicated from the master of the template 13 by the imprint process may be used.

An optical imprint process is employed in the above embodiments as the imprint process. However, the invention is not limited to the optical imprint. The invention is applicable to the other imprint process such as a thermal imprint.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A method of forming a template that transfers a pattern onto a transfer layer formed on a semiconductor substrate, the method comprising:
obtaining an error between a position of the pattern formed on the template and a reference position where the pattern is to be formed; and
processing an outer shape of the template in accordance with the obtained error.

2. The method according to claim 1, wherein
the reference position is formed on the semiconductor substrate.

3. The method according to claim 1, wherein
the reference position is decided by an absolute position measuring apparatus.

4. The method according to claim 1, wherein
a correction coefficient to correct the position of the pattern is calculated from the error, and the outer shape of the template is processed on the basis of the correction coefficient.

5. The method according to claim 4, wherein
the pattern has a position evaluating mark, and
the correction coefficient indicates coefficients of terms when a value of an equation (2) becomes minimum, the value of the equation (2) being obtained by substituting an equation (1) described below indicating the corrected position of the position evaluating mark into the equation (2) that is a square sum of a difference between the corrected position of the position evaluating mark and the error between an actual position of the position evaluating mark and the reference position of the position evaluating mark:
$$\begin{matrix}{dxi}^{′} = {k}_{1} + {k}_{3} \times xi + {k}_{5} \times yi + {k}_{7} \times {xi}^{2} + {k}_{11} \times {yi}^{2} + {k}_{13} \times {xi}^{3} + {k}_{19} \times {yi}^{3} \\ {dyi}^{′} = {k}_{2} + {k}_{6} \times xi + {k}_{4} \times yi + {k}_{12} \times {xi}^{2} & ( 1 ) \\ E = {\sum }_{k = 1}^{m} [ {( {dxi}^{′} - dxi )}^{2} ] + [ {( {dyi}^{′} - dyi )}^{2} ] & ( 2 )\end{matrix}$$
wherein the coefficient k1 indicates a positional deviation component in an x axis direction of the template, the coefficient k2 indicates a positional deviation component in a y axis direction of the template, the coefficient k3 indicates a scale component in the x axis direction, the coefficient k4 indicates a scale component in the y axis direction, the coefficient k5 indicates a rotational deviation component with respect to the x axis direction, the coefficient k6 indicates a rotational deviation component with respect to the y axis direction, the coefficient k7 indicates an eccentricity ratio component, the coefficient k11 indicates an arched component with respect to the y axis, the coefficient k12 indicates an arched component with respect to the x axis, the coefficient k13 indicates a tertiary magnification component with respect to the x axis, the coefficient k19 indicates a tertiary magnification component with respect to the y axis, i indicates an evaluation portion of the each of the position evaluating marks, m indicates a number of the position evaluating marks whose position is evaluated, xi indicates the reference position of the position evaluating mark in the x axis direction, yi indicates the reference position of the position evaluating mark in the y axis direction, dxi indicates the error between the reference position of the position evaluating mark and the actual position of the position evaluating mark in the x axis direction, dyi indicates the error between the reference position of the position evaluating mark and the actual position of the position evaluating mark in the y axis direction, dxi′ indicates the position of the position evaluating mark in the x axis direction after the correction, and dyi′ indicates the position of the position evaluating mark in the y axis direction after the correction.

6. The method according to claim 5, wherein
the outer shape of the template is processed in accordance with the correction coefficient having the maximum value.

7. The method according to claim 1, wherein
the side face of the template is processed in accordance with the error.

8. The method according to claim 1, wherein
the front surface of the template on which the pattern is formed is processed in accordance with the error.

9. The method according to claim 1, wherein
the back surface of the template that is opposite to the front surface of the template is processed in accordance with the error.

10. A method of manufacturing a semiconductor device using a template on which a pattern is formed beforehand, the method comprising:
obtaining an error between a position of the pattern formed on the template and a reference position where the pattern is to be formed;
processing an outer shape of the template in accordance with the obtained error;
correcting the error of the template by distorting the template through application of pressure to a side face of the template whose outer shape is processed; and
transferring the pattern onto a transfer layer formed on a semiconductor substrate by using the template in which the error is corrected.

11. The method according to claim 10, wherein
the reference position is formed on the semiconductor substrate.

12. The method according to claim 10, wherein
the reference position is decided by an absolute position measuring apparatus.

13. The method according to claim 12, wherein
the pressure to the side face of the template is applied by a clamper that holds the template.

14. The method according to claim 12, wherein
the side face of the template is processed in accordance with the error.

15. The method according to claim 12, wherein
the front surface of the template on which the pattern is formed is processed in accordance with the error.

16. The method according to claim 12, wherein
the back surface of the template that is opposite to the front surface of the template is processed in accordance with the error.

17. The method according to claim 10, wherein
a correction coefficient to correct the position of the pattern is calculated from the error, and the outer shape of the template is processed on the basis of the correction coefficient.

18. The method according to claim 17, wherein
the pattern has a position evaluating mark, and
the correction coefficient indicates coefficients of terms when a value of an equation (2) becomes minimum, the value of the equation (2) being obtained by substituting an equation (1) described below indicating the corrected position of the position evaluating mark into the equation (2) that is a square sum of a difference between the corrected position of the position evaluating mark and the error between an actual position of the position evaluating mark and the reference position of the position evaluating mark:
$$\begin{matrix}{dxi}^{′} = {k}_{1} + {k}_{3} \times xi + {k}_{5} \times yi + {k}_{7} \times {xi}^{2} + {k}_{11} \times {yi}^{2} + {k}_{13} \times {xi}^{3} + {k}_{19} \times {yi}^{3} \\ {dyi}^{′} = {k}_{2} + {k}_{6} \times xi + {k}_{4} \times yi + {k}_{12} \times {xi}^{2} & ( 1 ) \\ E = {\sum }_{i = 1}^{m} [ {( {dxi}^{′} - dxi )}^{2} ] + [ {( {dyi}^{′} - dyi )}^{2} ] & ( 2 )\end{matrix}$$
wherein the coefficient k1 indicates a positional deviation component in an x axis direction of the template, the coefficient k2 indicates a positional deviation component in a y axis direction of the template, the coefficient k3 indicates a scale component in the x axis direction, the coefficient k4 indicates a scale component in the y axis direction, the coefficient k5 indicates a rotational deviation component with respect to the x axis direction, the coefficient k6 indicates a rotational deviation component with respect to the y axis direction, the coefficient k7 indicates an eccentricity ratio component, the coefficient k11 indicates an arched component with respect to the y axis, the coefficient k12 indicates an arched component with respect to the x axis, the coefficient k13 indicates a tertiary magnification component with respect to the x axis, the coefficient k19 indicates a tertiary magnification component with respect to the y axis, i indicates an evaluation portion of the each of the position evaluating marks, m indicates a number of the position evaluating marks whose position is evaluated, xi indicates the reference position of the position evaluating mark in the x axis direction, yi indicates the reference position of the position evaluating mark in the y axis direction, dxi indicates the error between the reference position of the position evaluating mark and the actual position of the position evaluating mark in the x axis direction, dyi indicates the error between the reference position of the position evaluating mark and the actual position of the position evaluating mark in the y axis direction, dxi′ indicates the position of the position evaluating mark in the x axis direction after the correction, and dyi′ indicates the position of the position evaluating mark in the y axis direction after the correction.

19. The method according to claim 18, wherein
the outer shape of the template is processed in accordance with the correction coefficient having the maximum value.
